(19) United States
(12) Patent Application Publication
(10) Pub. No.: US 2004/0104384 A1
(43) Pub. Date: Jun. 3, 2004

(54) Growth of high temperature, high power, high speed electronics

(76) Inventors: Theodore D. Moustakas, Dover, MA (US); William Stacey, Somerville, MA (US); Philip Lamarre, Waltham, MA (US); Robert Scott Morris, Fairhaven, MA (US)

Correspondence Address: Philip Lamarre, 40 Amherst Avenue, Waltham, MA, 02451, US

(21) Appl. No.: 10/419,294

(22) Filed: Apr. 21, 2003

Related U.S. Application Data
(60) Provisional application No. 60/374,463, filed on Apr. 22, 2002.

(51) Int. Cl. H01L 29/06; H01L 31/0328; H01L 31/0336; H01L 31/072; H01L 31/109; H01L 31/0312; H01L 21/331; H01L 21/8222

(52) U.S. Cl. 257/13; 438/312; 257/77

(57) ABSTRACT

High quality epitaxial layers of monocrystalline materials can be grown overlying monocrystalline substrates such as SiC or sapphire by forming a compliant substrate for the growing the monocrystalline layers. Devices and methods for fabricating silicon carbide based heterojunction bipolar devices such as transistors and diodes. These devices are suitable for high power and/or high speed and/or high temperature electronic applications.

### BACKGROUND OF THE INVENTION

Semiconductor devices often include multiple layers of conductive, insulating, and semiconductive layers. Often, the desirable properties of such layers improve with the crystallinity of the layer. For example, the electron mobility of semiconductive layers improves as the crystallinity of the layer improves. Similarly, the free electron concentration of conductive layers and the electron charge displacement and electron energy recoverability of insulative or dielectric films improves as the crystallinity of these layers increases.

For many years, attempts have been made to grow monolithic thin films on a foreign substrate. To achieve optimal characteristics of the various layers, however, a monocrystalline film or high crystalline quality is desired. Attempts have been made on various substrates and these attempts have generally been unsuccessful because of lattice mismatches between the host crystal have caused the resulting layer of monocrystalline material to be of low quality.

Accordingly, a need exists for a semiconductor structure that provides a high quality monocrystalline film or layer over another monocrystalline material for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits. This monocrystalline material layer may be comprised of a semiconductor material, a compound semiconductor material, and other types of materials such as metals and non-metals.

### SUMMARY OF THE INVENTION

This disclosure describes an approach to the development of novel high power, high efficiency, high speed, high temperature semiconductor components for military and commercial applications where high power and high temperature electronics are needed.

The wide-bandgap semiconductors GaN and SiC hold great promise for high temperature and high-power electronic devices. This is due to the attractive properties these materials possess, such as wide energy bandgaps, high breakdown fields, high thermal conductivities, and high saturated electron velocities.

In addition, GaN and SiC have adequate electron mobilities and can readily be doped n and p type. GaN is generally grown on insulating sapphire substrates, which have poor thermal conductivity.

Therefore, the sapphire substrates limit efficient thermal management in high power GaN-based devices. By growing GaN on SiC one can make heterojunctions with excellent thermal properties.

This disclosure describes a novel method for growing on SiC substrates and novel devices which result from such growth. Other benefits and advantages of special semiconductor structures are also described.

### BRIEF DESCRIPTION OF DRAWINGS

The different aspects and advantages of this invention will become even more evident through the following description and several embodiments and by referring to the attached drawings, wherein:

FIG. 1 illustrates schematically, in cross section of a nitride based epitaxial growth showing buffer layer

FIG. 2 illustrates schematically, in cross section of a nitride based epitaxial growth showing no buffer layer

FIG. 3 illustrates schematically, in cross section, device structure in accordance with various embodiments of the invention.

FIG. 4 illustrates a current versus voltage for p-layer contact showing anomalously high current for layer thickness and doping.

FIG. 5 illustrates schematically, in cross section, device structure in accordance with various embodiments of the invention.

FIG. 6 illustrates a current versus voltage plot.

FIG. 7 illustrates a current versus voltage plot.

### DETAILED DESCRIPTION of the PREFERED EMBODIMENTS

The following description is intended as a general description of the invention, these preferred embodiments are used by way of illustration, but not by way of limitation to describe the invention.

The present invention describes growing GaN epitaxial layers on a SiC that can yield extremely good heterojunction diodes, transistors and other electronic devices.

The growth reported of GaN directly on SiC is significant for several reasons. First, the devices processed on the grown material were carefully characterized and demonstrated excellent electrical performance. Second, the GaN epi-layer was grown directly on the bulk p-type SiC and neither a GaN nor an AlN nucleation (buffer) layer or any other type of buffer layer was used.

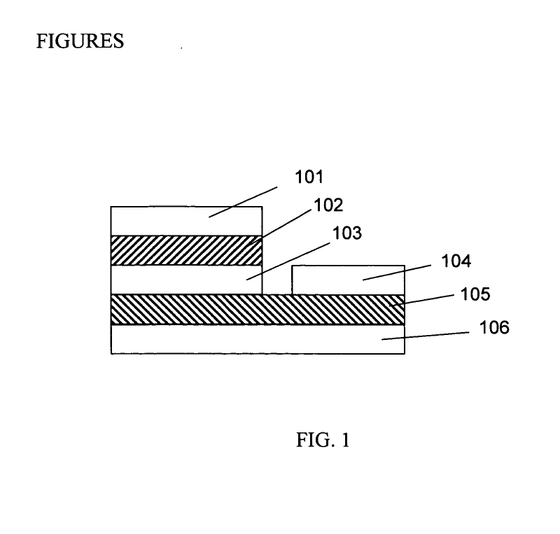

FIG. 1 shows a typical growth method to contrast with this invention for GaN on SiC or other substrate such as sapphire. 105 is the substrate to be grown on (For example, SiC or sapphire). 103 is a low temperature buffer layer used to improve growth of the monocrystalline layer. The low temperature buffer layer is sometimes GaN, or AlN or other material. 102 is the monocrystalline layer of GaN. 104 and 106 are ohmic frontside and backside contacts to the substrate.

### EXAMPLE 1

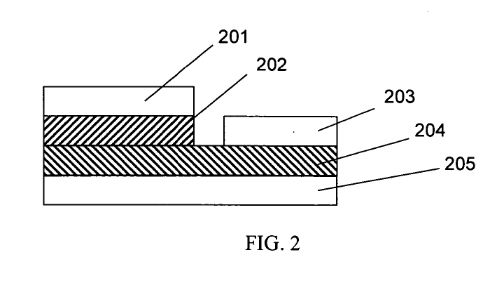

In accordance with a further embodiment of the invention FIG. 2 shows a preferred embodiment of this invention. 204 is the substrate material such as SiC. 202 is the high quality monocrystalline GaN material grown directly on the SiC without the high temperature buffer layer. 203 shows one method for forming an ohmic contact with the substrate, also known as a front side contact. 205 shows and alternate method for making contact with the substrate, also known as a backside contact. Either or both methods may be used to make contact with the substrate. 201 is an ohmic contact with the monocrystalline layer of GaN. Because there is no intermediate, low temperature, buffer layer, this structure forms a high quality heterojunction diode.

If the first epitaxial layer were grown of low doped material as shown in FIG. 2 202 Then the resulting diode structure would be capable of high voltage operation. Adding a second layer, which is highly doped n-type on top of the low doped n-layer, would be a slight modification, which would make a dramatic change in the breakdown voltage. Adding a low doped n-layer would increase the breakdown voltage. A high breakdown voltage is useful for a high power device. Adding refractory metal contacts and ion implanting to help with isolation and a superior device would be available for a range of applications.

There are at least two variations to this device.

1) FIG. 2 205 is n-SiC substrate highly doped. 204 is low doped n-SiC and 202 is highly doped p-GaN grown directly on the SiC.

2) FIG. 2 205 is again n-SiC substrate highly doped. 204 is low doped n-GaN and 202 is highly doped p-GaN.

Defining the mesas can be done through photolithographic masking and Inductively Coupled Plasma etching. ICP etching is preferred for this device for two reasons. First, ICP etching contains a confined plasma which increases the etch rate (an important consideration for a reasonable manufacturing process for SiC) and second, ICP is an inherently low damage process.

RIE and other dry etching techniques can be used but high damage dry etching would require longer wet etch to remove the damage.

To further improve device performance, the etched device could be implanted with ion species such as boron. The implantation will reduce surface currents thereby reducing premature breakdown.

The schematic device is illustrated in FIG. 2 is capable of high breakdown. The device is suitable for a high power, high current applications.

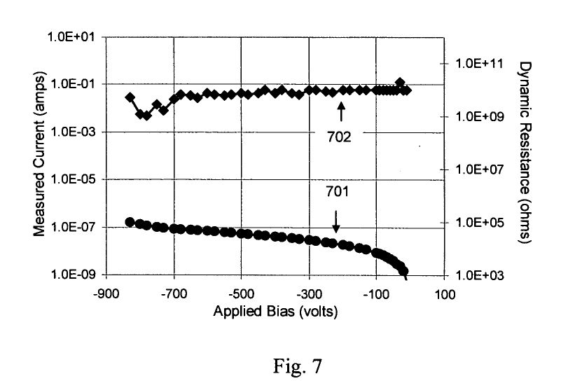

FIG. 7 displays a current versus voltage for a heterojunction diode of the type shown in FIG. 2. In FIG. 7 201 shows the current in the reverse direction with no evidence of breakdown past 800 volts. FIG. 7 702 is the dynamic resistance of the diode plotted versus applied bias. The zero bias resistance of this diode was in excess of 1.0×10⁹ ohms for a 1 mm diameter diode.

The electrical results plotted in FIG. 7 are significant because there are several steps not taken which would further improve the diodes performance. On this part there was no wet etch or junction termination implant which would reduce leakage. There was also no post-metallization anneal which would decrease the parasitic contact resistance. These additional process steps would have further improved the performance of the diode plotted in FIG. 7.

### EXAMPLE 2

In accordance with a further embodiment of the invention the substrates described in this application are SiC substrates. Although epi-polished the substrates have many fine scratches due to mechanical polishing with peak-to-valley roughness of about 100 nm, potentially the damaged layer can be even deeper. In addition, the SiC substrates have a thin film of native oxide that readily forms even under ambient conditions. Hence the surface preparation of SiC substrates prior to the epitaxial growth is critical. In addition to standard cleaning, the substrates were immersed in HF solution to etch surface oxides and to passivate the surface with hydrogen. Methods have been described of how to remove the surface roughness by annealing the substrate in hydrogen at temperatures of about 1600 C but they have not been applied during this stage of our work.

SiC and III-Nitrides have the same hexagonal symmetry and the epitaxial growth follows the substrate symmetry:

(0001)GaN//(0001)SiC and [11-20]GaN//[11-20]SiC

Si—N and Al—C bonds are the preferred bonding configurations in a Si- and C-terminated SiC faces respectively. Based on these findings it is advantageous to start the epitaxial growth on a Si-terminated SiC surface with a monolayer of nitrogen. However one needs to be careful not to create a thick amorphous SiN layer which would prevent the epitaxial growth of GaN.

In general the epitaxial growth of GaN on SiC is preceded by a nucleation buffer layer (either AlN or GaN). However in our work since we are aiming to form a heterojunction between SiC and GaN such nucleation buffer layers cannot be employed. Instead we use two methods for direct nucleation and growth of the active layer of GaN

Approach#1. The SiC wafers after their chemical cleaning and hydrogen passivation were introduced in the MBE chamber and annealed for a short period at temperatures of about 800 C. After that they were exposed momentarily to a nitrogen plasma prior to the initiation of the GaN epitaxial growth. This should lead to GaN with Ga-polarity

Approach #2. In the second approach the GaN epitaxial growth was initiated by flashing the SiC substrate with Ga and exposing it to a nitrogen plasma. This process was shown to lead to a 2×2 surface reconstruction which is characteristic of Ga-polarity. Most dislocations at the SiC GaN interface are ⅓ [11-20] edge dislocations with a density of about 2×10⁹ cm⁻² near the top of the film. It is believed that for thicker films the density of dislocations would be considerably reduced due to dislocation interaction and annihilation. In addition to threading dislocations, some dislocation loops are also seen close to the interface. There was no evidence of cubic domains and planar defect stacking mismatch boundaries.

### EXAMPLE 3

In accordance with a further embodiment of the invention a new structure is described. The new structure is appropriate for very high speed applications such A/D converter.

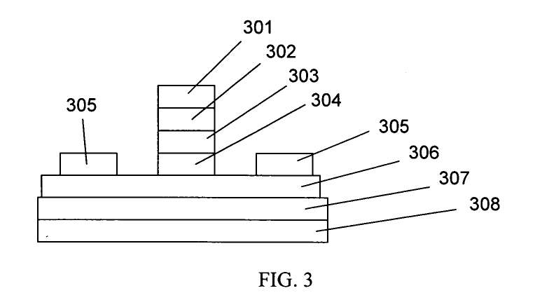

This transistor also has the requirement of a relatively high emitter-collector breakdown. In fact, simulations predict that a transistor with a higher breakdown should have a better high frequency performance, because of the trade-off between collector transit time and collector charging time. The epi structure for the transistor is shown in FIG. 3.

Silicon Carbide is a suitable material for the collector for two reasons:

1) SiC has a very high breakdown field enabling breakdown voltages (Vbr) up to 20 V for narrow collector widths.

2) SiC has a high saturated drift velocity to provide a short depletion layer transit time.

The emitter consists of three layers, grown in this order from the base region;

(Emitter Layer 1, FIG. 3 304) Lightly-doped layer of AlGaN which creates a relatively wide emitter-base depletion layer and hence a low emitter-base capacitance and consequent short emitter charging time.

(Emitter Layer 2, FIG. 3 303) A highly-doped graded layer of AlGaN to GaN which creates a transformation from AlGaN to GaN without any abrupt transitions which might create a resistive barrier to current flow.

(Emitter Layer 3, FIG. 3 302) Highly-doped, thin GaN layer is added to the stack to reduce emitter contact resistance.

FIG. 3 shows a typical configuration for this preferred embodiment. 308 is the Substrate which is n-SiC greater at a typical thickness of 100 microns and a doping of 1×10¹⁸. 307 is the n-SiC collector, approximately 1,400 Angstroms thick, 6×10¹⁷ doping. 306 is the base layer, p-GaN 500 Angstroms greater than 1×10¹⁸ doping. 305 is the base contact metal. 301 is the emitter contact metal and 305 is the base contact metal.

The base region consists of a p+ GaN (Mg doped) layer doped to the maximum possible level. Since one must use a thin base layer to achieve both high speed and high low-frequency gain, the base spreading resistance (which affects Fmax) is increased and has to be minimized by achieving as low as possible a base resistivity.

A primary reason for this embodiment is to develop a transistor with an increased operating voltage compared to currently available devices without losing response time and eventually to monolithically integrate this transistor into a full A/D converter. Simulations using reasonable dimensions and known material properties predict that the cutoff frequency for the proposed device does not continually improve as the operating voltage is lowered but has a peak value due to the trade-off between collector charging time and transit time.

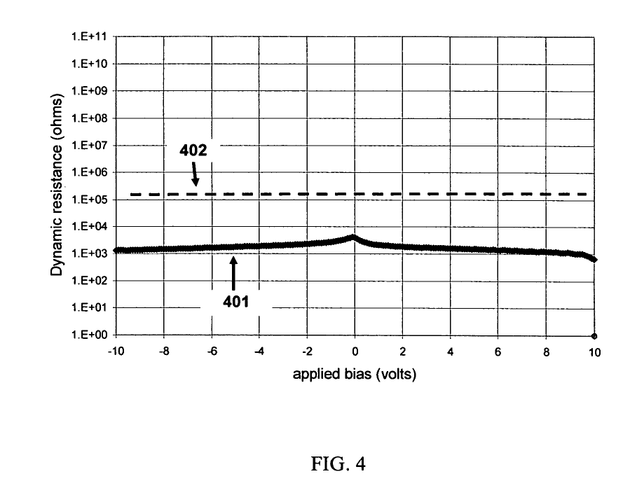

The Base to Base resistance on this preferred embodiment was substantially lower than expected. FIG. 4 401 is the measured base to base resistance of approximately 1,000 ohms. The expected resistance for the given geometry and doping is approximately 100,000 ohms as shown by the dashed line in FIG. 4 402.

Photoactivation of the device using an ultraviolet (UV) light source was investigated as a potential means of providing gate bias without a physical contact and as a possible means of making a circuit with integral light-emitting diodes and phototransistors to achieve increased speed and superior input/output isolation.

One of the fundamental constraints limiting the performance of electrical A/D converter technologies is the aperture jitter caused by clock jitter and sampling gate variation. As a solution, the idea of combining the low jitter and high-speed advantages of photonics with electrical A/D converters in a hybrid system has spawned a number of photonic A/D conversion systems in recent years. There is a clear precedent for using optical devices in A/D converters. We have an advantage that our device is naturally photosensitive. This makes and additional method to bias our gate and may be advantageous for analog to digital conversion.

### EXAMPLE 4

In accordance with a further embodiment of the invention a new structure is described. The new structure is appropriate for very high power applications such as a high power photo switch.

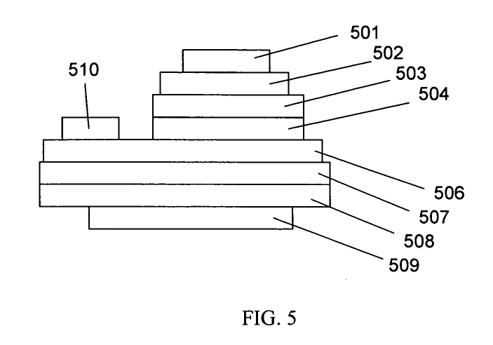

FIG. 5 shows a typical configuration for this preferred embodiment. 509 is the collector ohmic contact. 508 is the SiC substrate. 507 is the collector, n-SiC 2.0×10¹⁵ a nominal thickness for this layer would be 60 microns depending on speed and power requirements. 506 is the p-GaN base layer and again the thickness and doping may vary but a nominal value would be 1.0×10¹⁸ about 2,000 Angstroms thick. 504 is the emitter capacitance reduction layer. The emitter capacitance layer is n-AlGaN and the thickness is 1,000 Angstroms and the nominal doping is 1×10¹⁶. The next layer 503 is the n-AlGaN emitter spreading layer 1×10¹⁸ and 1,000 Angstroms thick. 502 is the final epitaxial layer in this structure. The final layer is n-GaN 1×10¹⁹ 500 Angstroms thick. 501 the emitter ohmic contact. 510 is the base layer ohmic contact.

It is important to note one aspect of this invention is that the emitter has three epitaxial layers. Each layer has a specific function.

(Emitter Layer 1—FIG. 5 504) Lightly-doped layer of AlGaN which creates a relatively wide emitter-base depletion layer and hence a low emitter-base capacitance and consequent short emitter charging time.

(Emitter Layer 2—FIG. 5 503) Thicker highly-doped layer of AlGaN which reduces the emitter resistance to the base regions remote from the emitter contact necessitated by the need of an optical window. This conducting transparent layer is the key to device operation, allowing optically generated carriers to induce emitter injection without having to diffuse sideways to the emitter contact. It is very likely that the minority carrier lifetimes in the base are so short that carriers would not have time to diffuse as far as the emitter contact, as in a conventional phototransistor, before recombination took place.

(Emitter Layer 3—FIG. 5 502) Highly-doped, thin GaN layer is added to the stack to reduce emitter contact resistance. This layer will be removed from the window to allow for penetration of the light signal.

The response time of the transistor is predominantly determined by the collector width. Thus the requirements for the other time constants, which are to some extent set by the device geometry, are not as stringent as for most high frequency devices.

Simulations show that the speed of the device is not critically affected by the emitter contact width (which changes only in the third decimal place when the finger width varies from 0.5 to 2 um) or the separation of emitter and base contact fingers at the high voltage end of operation. This simulation is encouraging with the implication that the transistor surface can be predominantly window with a small fraction of emitter contact area.

Activation of the transistor is achieved by illuminating the base region with photon energies lying in the range 3.40-3.95 eV. This represents the difference in the bandgaps of GaN and Al_{0.25}Ga_{0.75}N. By using a highly-doped, highly conducting layer of AlGaN on the top surface of the emitter, it is predicted that sideways current flow from the emitter contact will enable roughly uniform injection from the emitter into the base as a result of carriers generated in the base by the optical signal. Therefore, the light intensity required is reduced by the Common Emitter Gain of the transistor. Exactly how large the gain will be cannot be determined at this time. Although a portion of the light will pass through the base into the collector, a negligible amount will penetrate more than a few microns into the collector. This may be important in suppressing current filamentation, seen in other photo-activated devices, since the formation of the filaments seems to require the presence of photons and a high field.

Reliability issues with optically activated solid-state switches made with Si and GaAs have been widely reported. There is less available information for SiC.

The Photo-HBT proposed here has two advantages for eliminating current filamentation listed below:

1) The collector will not be biased above the breakdown voltage and at the onset of the pulse as the collector current starts to rise, the voltage will drop rapidly, and by our estimates out of the voltage range when filamentation occurs.

2) The region which is carrying the current (the collector) is not illuminated. The process of filamentation is poorly understood, but seems to be associated with the generation of carriers by the optical signal and not just the high electric field.

This transistor is intended to switch rapidly (˜1 nsec) from a blocking voltage of 20 kV to a low resistance state passing 200A at an estimated voltage drop of ˜5 V. If this transition takes place along a resistive (100 ohm) load line, then an instantaneous peak value of dissipated power of 1 Megawatt will occur at the mid-point. However, because of the short pulse duration the total energy dissipated by the transistor during the switching period is only ˜0.7 mJ. Assuming that the energy is concentrated in the 70 um thick collector region, the predicted temperature rise in a 2 mm×2 mm device will be<1 deg C. for a single pulse. Similarly, assuming a 1 nsec switch-off speed an equal amount of dissipated energy will be created during the switch off phase. During the flat portion of the pulse (20-200 nsec) a negligible amount of energy is dissipated.

Taking the worst case Pulse repetition Frequency (PRF) of 1 kHz, an average dissipated power of around 1.5 W is predicted. The thermal impedance of a 2 mm×2 mm chip, 25 mils thick calculates to be around 0.3 deg C./W, leading to an average temperature rise of 0.45 deg.

The transistor can be photo activated but the transistor can also be electrically activated. The transistor can be electrically activated by connecting to the ohmic contact on the base layer (see FIG. 5 510)

There are obvious advantages to being able to switch the transistor optically. The perfect isolation of the input signal means that series connection of transistors to achieve a higher switching voltage can be carried out without any loss of speed and without having to resort to a sequential switching operation of the individual devices.

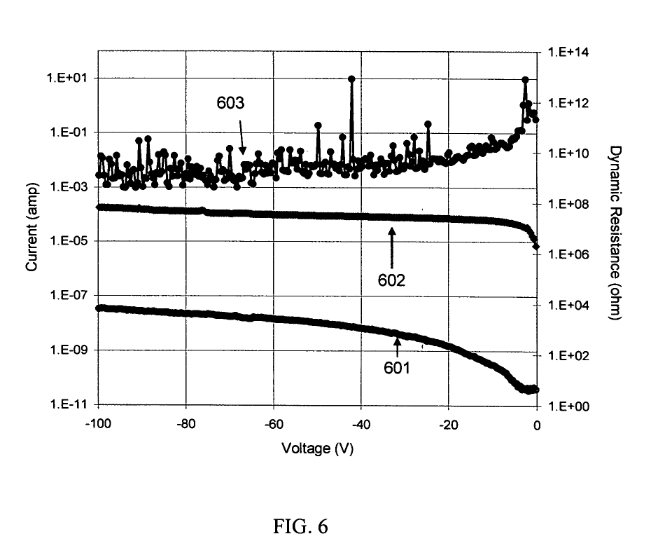

FIG. 6 displays current versus voltage for a device manufactured to the epitaxial layer structure shown in FIG. 5. 601 is dark current. 602 is photogenerated current. 603 is the dynamic resistance. The gain for this photo-Heterojunction Bipolar Transistor (photoHBT) is measured to be approximately 3.0 This is the first report of a direct growth GaN/SiC photo-HBT reported. Reverse breakdown of this device was in excess of 1,200 volts.

That which is claimed is:

1. A method for forming a monocrystalline layer of GaN directly on SiC

2. Using the method of 1. a high quality heteojunction diode is formed.

3. Using the method of 1. a high quality high speed heterojunction bipolar transistor is formed

4. Using the method of 1. a high quality high power photo-activated heterojunction bipolar transistor is formed

5. Using the method of 1. a high quality high power electrically-activated heterojunction bipolar transistor is formed

6. Using the method of 1. an anomalously low p-GaN resistivity can be achieved.
